(19) United States
(12) Patent Application Publication
(10) Pub. No.: US 2026/0350255 A1
(43) Pub. Date: Nov. 5, 2026

(54) CONFIGURATION OF INDUSTRIAL HARDWARE ENCLOSURES

(71) Applicant: Schneider Electric Systems USA, Inc., Foxborough, MA (US)

(72) Inventors: Mahmoud Abdelrahman Morsy, Fayoum (EG); Shady Saad Bakry, Cairo (EG)

(21) Appl. No.: 19/198,769

(22) Filed: May 5, 2025

(51) Int. Cl. G06F 30/17

(52) U.S. Cl. CPC G06F 30/17

(57) ABSTRACT

A method for configuring at least one industrial hardware enclosure includes receiving input data associated with the industrial hardware enclosure. The input data includes information related to one or more variables, one or more constraints, and one or more objectives. A layout model is defined using the variables, constraints, and objectives. The layout model represents a task of configuring the industrial hardware enclosure based on the input data. A plurality of candidate arrangements is generated by systematically adjusting values for the variables within the layout model. A solution arrangement that satisfies the constraints and is aligned with at least one of the objectives is selected from the plurality of candidate arrangements. Technical documentation is generated based on the solution arrangement. The technical documentation includes a layout diagram illustrating placement of one or more of components and wiring within the industrial hardware enclosure.

### BACKGROUND

Industrial control systems are used to manage the electrical, instrumentation, and control aspects of machines and processes in various industrial environments. Known industrial control systems include one or more components housed within an enclosure to regulate operations, such as programmable logic controllers (PLCs), input/output (I/O) devices, human-machine interfaces (HMIs), networking devices, circuit breakers, overload relays, and terminal blocks, among others. An industrial hardware enclosure protects these components from environmental conditions such as heat, cold, moisture, contaminants, and mechanical abuse, as well as safeguarding workers from electrical hazards. However, merely assembling electrical components within an enclosure without careful planning can result in an inefficient or improper configuration, leading to increased assembly time, poor space utilization, and/or excessive wiring complexity, ultimately driving up costs and/or operational challenges. Moreover, improper wiring organization can lead to signal interference, excessive voltage drops, difficulty in troubleshooting, and compliance issues with industry standards. Traditional methods for designing and configuring industrial hardware enclosures rely heavily on the expertise of engineers to determine a suitable layout, which often involves a manual trial-and-error process that can be tedious, time-consuming, and prone to inconsistencies, especially as system complexity increases.

### SUMMARY

Aspects of the present disclosure enable industrial hardware enclosures to be configured effectively, efficiently, and consistently. In one aspect, a method is provided for machine learning-assisted configuration of at least one industrial hardware enclosure. The method includes receiving input data associated with the at least one industrial hardware enclosure. The input data includes information related to one or more variables, one or more constraints, and one or more objectives. A layout model is defined using the variables, constraints, and objectives. The layout model represents a task of configuring the industrial hardware enclosure based on the input data. A plurality of candidate arrangements is generated by systematically adjusting values for the variables within the layout model. A solution arrangement that satisfies the constraints and is aligned with at least one of the objectives is selected from the candidate arrangements. Technical documentation is generated based on the solution arrangement. The technical documentation includes a layout diagram illustrating placement of components and/or wiring within the industrial hardware enclosure.

In another aspect, a computing system is provided for machine learning-assisted configuration of at least one industrial hardware enclosure. The computing system includes a model generator that receives input data associated with the industrial hardware enclosure. The input data includes information related to one or more variables, one or more constraints, and one or more objectives. The model generator defines a layout model using the variables, constraints, and objectives. The layout model represents a task of configuring the industrial hardware enclosure based on the input data. The computing system includes a layout generator that uses the layout model to generate a plurality of candidate arrangements by systematically adjusting values for the variables within the layout model, and determines a solution arrangement that satisfies the constraints and is aligned with at least one of the objectives. The computing system includes a document generator that generates technical documentation based on the solution arrangement. The technical documentation includes a layout diagram illustrating placement of components and/or wiring within the industrial hardware enclosure.

In yet another aspect, a system is provided. The system includes an industrial hardware enclosure, a plurality of components, wiring, and a computing device configured to receive input data associated with the industrial hardware enclosure. The input data includes information related to one or more variables, one or more constraints, and one or more objectives. The computing device is configured to define a layout model using the variables, constraints, and objectives. The layout model represents a task of configuring the industrial hardware enclosure based on the input data. The computing device is configured to use the layout model to generate a plurality of candidate arrangements by systematically adjusting values for the variables within the layout model, determine a solution arrangement that satisfies the one or more constraints and is aligned with at least one of the one or more objectives, and generate technical documentation based on the solution arrangement. The technical documentation includes a layout diagram illustrating placement of the components and/or wiring within the industrial hardware enclosure.

Other aspects and features of the present disclosure will be in part apparent and in part pointed out herein. This Summary is provided to introduce a selection of concepts in a simplified form that are further described below in the Detailed Description. This Summary is not intended to identify key features or essential features of the claimed subject matter, nor is it intended to be used in isolation as an aid in determining the scope of the claimed subject matter.

### BRIEF DESCRIPTION OF THE DRAWINGS

Aspects of the present disclosure are described in detail below with reference to the attached drawing figures, wherein:

FIG. 1 is a block diagram illustrating an example environment.

FIG. 2 is a block diagram illustrating an example system for configuring an industrial hardware enclosure for use in an environment, such as the environment shown in FIG. 1;

FIG. 3 is a block diagram illustrating a suboptimal configuration of an industrial control system including two industrial hardware enclosures.

FIG. 4 is a block diagram illustrating a suitable configuration of the industrial control system shown in FIG. 3, which may be determined using the system shown in FIG. 2.

FIG. 5 is a flowchart illustrating an example method for configuring an industrial hardware enclosure, such as the industrial hardware enclosures shown in FIG. 3; and

FIG. 6 is a computer architecture diagram illustrating a computing system that may be used to perform one or more computing operations described herein, such as those implemented by the system shown in FIG. 2 and/or the method shown in FIG. 5.

Corresponding reference numbers indicate corresponding parts throughout the drawings.

### DETAILED DESCRIPTION

Aspects of the disclosure relate to systems and methods for machine learning-assisted configuration of industrial hardware enclosures. The systems and methods described herein allow industrial hardware enclosures to be configured through a systematic approach that models the layout of an industrial hardware enclosure as a structured design problem. This approach incorporates variables (parameters that can change), constraints (parameters that must be followed), and objectives (parameters that are desirable) to determine an arrangement of components and wiring within the industrial hardware enclosure. Examples include receiving input data including information about variables, constraints, and objectives associated with at least one industrial hardware enclosure, and defining a layout model that represents a task of configuring the industrial hardware enclosure based on the variables, constraints, and objectives. A plurality of candidate arrangements is generated by evaluating different combinations and values of the variables within the layout model, and a solution arrangement that satisfies the constraints and is aligned with at least one of the objectives is selected from the plurality of candidate arrangements. Technical documentation is generated based on the solution arrangement, including a layout diagram illustrating component placement and/or wiring routes within the industrial hardware enclosure. Examples described herein ensure that the components and/or wiring are arranged logically to meet project requirements efficiently and consistently while balancing other design considerations.

As used herein, the term “wire” refers to a single conductor used for carrying electrical current or signals, and the term “cable” refers to a bundle of two or more wires. A wire may be solid or stranded, wherein a stranded wire comprises multiple smaller gauge conductive filaments twisted or bundled together to form a single conductor. A cable is typically enclosed as a unit within an outer jacket or sheath to provide protection, organization, or enhanced signal integrity. As used herein, the term “wiring” refers collectively to one or more wires and/or cables arranged to establish connectivity between components. Wiring encompasses both the physical elements (i.e., wires and cables) and their arrangement or organization (e.g., routing, bundling, termination, and connection).

The systems and methods disclosed herein provide a technological solution to technical problems by using advanced modeling and algorithmic techniques to translate a real-world engineering challenge into a structured set of mathematical relationships that enable machine learning-assisted configuration of industrial hardware enclosures. The technical effect of the systems and methods described herein is achieved by using a computing system configured to perform one or more of the following operations: (i) receiving input data associated with the at least one industrial hardware enclosure; (ii) defining a layout model using one or more variables, one or more constraints, and one or more objectives; (iii) generating a plurality of candidate arrangements by systematically adjusting values for the variables within the layout model; (iv) selecting, from the candidate arrangements, a solution arrangement that satisfies the constraints and is aligned with at least one of the objectives; and (v) generating technical documentation based on the solution arrangement.

Aspects of the present disclosure provide for a computing system that performs one or more operations within an environment including a plurality of devices coupled to each other via a network (e.g., a local area network (LAN), a wide area network (WAN), the internet). The systems and methods described herein may be implemented using computer programming or engineering techniques including computer software, firmware, hardware, or a combination or subset thereof. Unless defined otherwise, all technical and scientific terms used herein have the same meaning as commonly understood by one of ordinary skill in the art to which the present disclosure belongs. Although any methods and materials similar to or equivalent to those described herein can be used in the practice or testing of the present disclosure, some preferred methods and materials are described below.

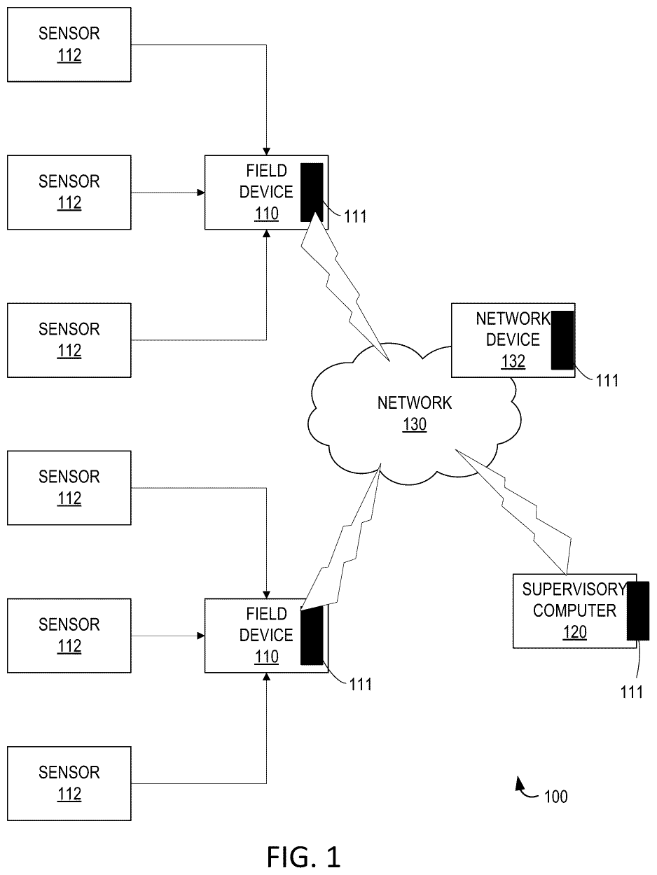

FIG. 1 shows an example environment 100 in which one or more machines and/or processes may be managed and/or automated. As shown in FIG. 1, the environment 100 may be an industrial environment including a plurality of entities such as field devices 110, sensors 112, and/or supervisory computers 120. The field devices 110, sensors 112, and/or supervisory computers 120 may each include an industrial hardware enclosure housing one or more components that monitor and/or control one or more machines and/or processes within the environment 100. For example, a field device 110 may be or include PLC 111 configured to receive or collect sensor information from one or more sensors 112. Additionally or alternatively, the field device 110 may be or include a remote terminal unit (RTU), a programmable automation controller (PAC), and/or an intelligent electronic device (IED) configured to receive or collect sensor information from one or more sensors 112. In some examples, the field devices 110 are spaced to monitor and/or control one or more machines and/or processes across a widely-dispersed infrastructure. Although described in the context of the example environment of FIG. 1, it is to be understood that aspects of the present disclosure may be employed in a distributed control system (DCS) environment.

A supervisory computer 120 may be used to monitor and/or control the field devices 110 and/or sensors 112. For example, the supervisory computer 120 may receive or collect the sensor information from the field devices 110 and analyze the sensor information to facilitate monitoring and/or controlling one or more machines and/or processes. In some examples, the supervisory computer 120 may be or include a PLC 111 configured to receive or collect the sensor information, and/or other device information, from one or more field devices 110. The supervisory computer 120 may be configured to automatically operate and/or reconfigure one or more field devices 110 based on the sensor information and/or device information.

The supervisory computer 120 is communicatively coupled to the field devices 110 via a network 130. In some examples, the network 130 is an industrial control system (ICS) network that connects the supervisory computer 120 to the field devices 110 for supporting automation and process control applications. The connections between the supervisory computer 120 and the field devices 110 may be wired and/or wireless. As shown in FIG. 1, the network 130 may include one or more network devices 132. In some examples, the network device 132 may be or include a PLC 111 configured to receive or collect sensor information and/or device information from the field devices 110 and/or supervisory computer 120. Additionally or alternatively, the network device 132 may be or include a firewall, unidirectional gateway, and/or data diode that facilitates protecting the field devices 110 and/or supervisory computer 120 from external threats.

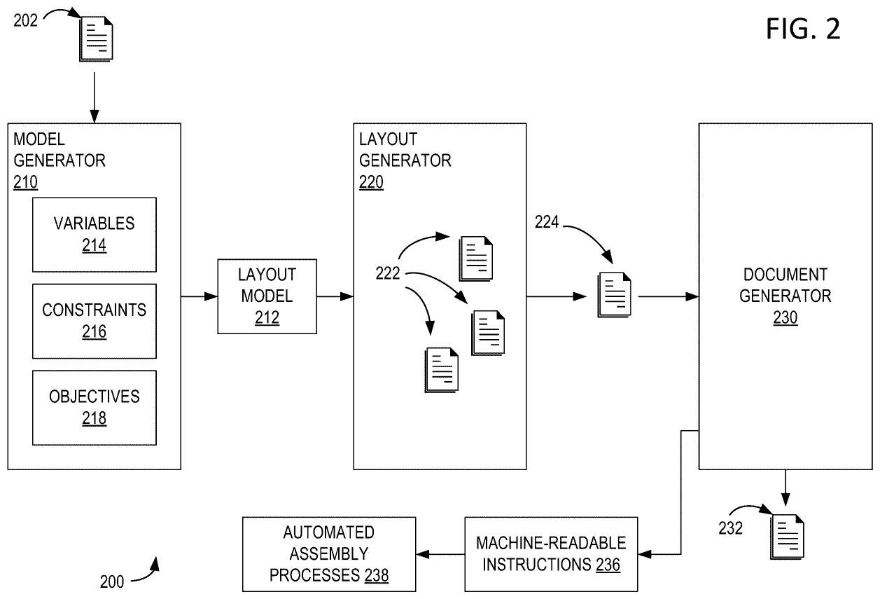

FIG. 2 shows a system 200 for machine learning-assisted configuration of at least one industrial hardware enclosure for use in an environment (e.g., environment 100). The system 200 automates the design and configuration process, reducing manual effort and improving efficiency, organization, and compliance with industry standards. Example enclosures may include, but are not limited to, control panels, operator consoles, terminal boxes, junction boxes, network/communication cabinets, marshalling cabinets, rack enclosures, and the like.

The system 200 is configured to receive input data 202 associated with at least one enclosure. The input data 202 may include various parameters that influence or contribute to the design and configuration of enclosures. Some parameters are directly related to the components and/or wiring within the enclosure, such as physical specifications (e.g., dimensions, required clearances, number of rack units, weight, mechanical stress factors, mounting options, material composition, cable entry provisions, ingress protection ratings), power specifications (e.g., voltage ratings, power consumption, power distribution requirements, power quality factors), thermal specifications (e.g., heat output, operating temperature ranges, heat dissipation requirements), and connectivity and compatibility specifications (e.g., communication protocols, termination types, signal types, voting designations, interface standards integration requirements, wiring segregation requirements, bus system compatibility). In addition, input data 202 may also include broader design considerations, such as environmental conditions (e.g., temperature ranges, humidity ranges, exposure to chemicals, contaminants, dust, or particulates), regulatory and safety considerations (e.g., safety codes, certifications, industry standards, hazardous area classifications, fire resistance ratings), and/or user-related factors (e.g., accessibility requirements, maintenance requirements, expandability, budget, best practices). In some examples, the input data 202 may include a bill of materials (BOM) or a schedule specifying one or more components and/or wiring to be incorporated into the enclosure. Example components may include, but are not limited to, terminal blocks, relays, contactors, power supply and distribution components, transformers, circuit protection devices (e.g., circuit breakers, surge suppressors, and fuses), networking equipment, motor control devices (e.g., PLCs, VFDs), and HMI components, along with structural elements such as enclosures, backplates, grounding panels, ducts, and rails.

The system 200 includes a model generator 210 configured to process the input data 202 to generate one or more layout models 212. In some examples, the model generator 210 may ensure that project criteria are met by defining the layout model 212 as a structured representation of the task of designing and/or configuring an enclosure based on the input data 202. To achieve this, the layout model 212 may integrate or incorporate various design factors to provide a systematic framework for enclosure configuration. For example, the model generator 210 may analyze the input data 202 to identify or determine one or more variables 214, one or more constraints 216, and one or more objectives 218 and then use the determined variables 214, constraints 216, and objectives 218 to collectively define the layout model 212, guiding the arrangement of components and wiring within the enclosure while balancing design requirements, technical constraints, and performance goals.

Variables 214 include or represent the decision points or parameters that may be adjusted to determine or influence an arrangement 222 of components and wiring within an enclosure. Example variables 214 may include, but are not limited to, the number and placement of components and wiring. Constraints 216 include or represent limitations, requirements, or parameters that must be satisfied or adhered to for an arrangement 222 to be valid. Example constraints 216 may include, but are not limited to, space constraints (e.g., number of rails, rail length, etc.), adjacency constraints (e.g., requiring certain components to be placed next to each other, segregating safety circuits from other circuits, maintaining minimum spacing around components for cooling), and wiring segregation constraints (e.g., requiring certain types of signals to be routed separately to prevent interference, keeping low-voltage instruments and communication cables away from higher voltage power cables). Objectives 218 include or represent the goals, intents, or parameters that establish criteria for determining or evaluating whether an arrangement 222 is desirable or preferable. Example objectives 218 may include, but are not limited to, reducing component count, logically arranging components, preserving usable spare space within the enclosure, reducing wiring complexity, and balancing wiring distribution.

In some examples, input data 202 may be processed using natural language processing (NLP) techniques, data mining algorithms, or computer vision tools to extract relevant information for classification as variables 214, constraints 216, and/or objectives 218. For example, unstructured design documents may be parsed to identify key terms that indicate or correspond to variables 214, constraints 216 (e.g., space limits), and/or objectives 218 (e.g., improving system reliability). Once the input data 202 is appropriately classified, it can be incorporated into the layout model 212, ensuring that the layout model 212 accurately reflects the task of configuring the enclosure based on the input data 202.

In some examples, the model generator 210 may employ one or more machine learning techniques to assist in refining the layout model 212. For example, machine learning techniques may be applied to identify patterns or correlations within large sets of unstructured input data 202, helping to automatically classify and structure the input data 202 into the appropriate categories for the layout model 212. In some examples, linear programming techniques may be applied when the variables 214, constraints 216, and objectives 218 define a task with well-defined factors that are relatively easy to express mathematically (e.g., optimizing component and wiring placement while minimizing cost or material usage). Integer linear programming in accordance with a preferred embodiment provides an improved layout model 212 as variables 214 are integers. Moreover, non-linear programming techniques may be applied when the variables 214, constraints 216, and objectives 218 define a more complex task with interdependent, and potentially competing, factors (e.g., balancing thermal dissipation while maintaining functional grouping, efficient power distribution, and minimizing electromagnetic interference). The machine learning techniques facilitate efficient exploration of a broad solution space by allowing the model generator 210 to iteratively test or evaluate various combinations of variables 214, constraints 216, and/or objectives 218 without requiring exhaustive testing of all possible combinations. For example, the model generator 210 may use one or more metaheuristic algorithms to generate and refine the layout model 212 by: (i) generating a population of candidate models based on different combinations of variables 214, constraints 216, and objectives 218; (ii) evaluating each candidate model against predetermined criteria (e.g., validity, reliability); (iii) selecting one or more high-performing candidate models; (iii) applying one or more genetic operations (e.g., crossover, mutation) on the selected candidate models to generate new combinations of variables 214, constraints 216, and objectives 218; and (v) repeating one or more of these operations until a termination criterion is met (e.g., reaching a maximum iteration count or converging on an optimal solution).

The system 200 includes a layout generator 220 configured to use the layout model 212 to assess or evaluate different arrangements 222 and identify or determine a solution arrangement 224 that satisfies all constraints 216 (or does not violate any) and best fits or aligns with the objectives 218. For example, the layout generator 220 may evaluate various component and/or wiring placements based on flow (e.g., grouping AC and DC components in separate sections, physically separated by partitions or barriers), thermal considerations (e.g., exposing heat-generating components such as power supplies and variable frequency drives (VFDs) to airflow, positioning heat-sensitive components near cooling devices such as heat sinks and fans), and/or functional organization (e.g., grouping components by function or size, routing sensitive wiring away from high-power components to prevent electromagnetic interference and signal degradation). The layout generator 220 may systematically adjust a value for each variable 214 to generate a plurality of arrangements 222, and then evaluate the arrangements 222 based on their compliance with constraints 216 and alignment with objectives 218 to determine the solution arrangement 224. In some examples, the layout generator 220 may iteratively assess or evaluate both physical and electrical considerations, alternating between them until the solution arrangement 224 is determined.

In some examples, the layout generator 220 may employ one or more machine learning techniques to assist in refining the solution arrangement 224. The machine learning techniques may incorporate linear and/or non-linear programming methods, depending on the complexity of the variables 214, constraints 216, and objectives 218. The machine learning techniques facilitate efficient exploration of a broad solution space by allowing the layout generator 220 to iteratively test or evaluate various combinations of values for the variables 214 without requiring exhaustive testing of all possible combinations. For example, the layout generator 220 may use one or more metaheuristic algorithms to generate and refine the solution arrangement 224 by: (i) generating a population of candidate arrangements based on different combinations of values for the variables 214; (ii) evaluating each candidate arrangement based on compliance with constraints 216 and alignment with objectives 218; (iii) selecting one or more high-performing candidate arrangements; (iv) applying one or more genetic operations (e.g., crossover, mutation) on the selected candidate arrangements to generate new combinations of values for the variables 214; and (v) repeating one or more of these operations until a termination criterion is met (e.g., reaching a maximum iteration count or converging on an optimal solution).

The system 200 includes a document generator 230 configured to process the solution arrangement 224 to generate technical documentation 232. In some examples, the document generator 230 may ensure that the technical documentation 232 facilitate the manufacturing, installation, and/or maintenance of the enclosure and support quality assurance, regulatory compliance verification, and/or system troubleshooting. To achieve this, the technical documentation 232 may cover various aspects of the enclosure, such as inventories, component and wiring assignments, hardware and power distribution specifications, thermal management, input/output configurations, and/or safety compliance. For example, the technical documentation 232 may include schematics that define how components are coupled together by describing point-to-point connections. In some examples, at least one of the technical documentation 232 may be generated to comply with industry standards and/or regulatory requirements. Example technical documentation 232 may include, but are not limited to, a BOM including a detailed list of makes, models, and quantities, a layout diagram illustrating interior dimensions and component and wiring placement, a schedule of tags and nameplates, a power distribution drawing with grounding provisions, a block diagram illustrating PLC/HMI, data, and networking with device addresses and communication settings, a drawing illustrating input/output modules and field termination strips, an intelligent device drawing for VFDs, motion controllers, servos, safety controllers, and similar instruments or devices, a functional diagram illustrating system operation, assembly instructions, and a compliance checklist.

In some examples, the system 200 integrates with automated assembly processes to enable direct execution of the solution arrangement 224. For example, components and/or wiring may be automatically assembled based on the solution arrangement 224 and/or technical documentation 232 using robotic assembly systems, computer-aided manufacturing (CAM) processes, and/or programmable assembly lines that convert the solution arrangement 224 and/or technical documentation 232 into machine-readable formats, such as a machine-readable set of instructions 236. In an embodiment, automated assembly processes 238 are responsive to the machine-readable instructions for guiding or controlling automated equipment to position and secure components within the enclosure and/or route wiring. Advanced techniques, such as robotic pick-and-place systems, precision-guided wiring placement, and automated soldering or crimping, may be utilized to ensure accuracy, efficiency, and consistency. Additionally, real-time monitoring and quality control mechanisms, such as computer vision and sensor-based verification, may be utilized to detect misalignments and/or deviations from the solution arrangement 224 and/or technical documentation 232.

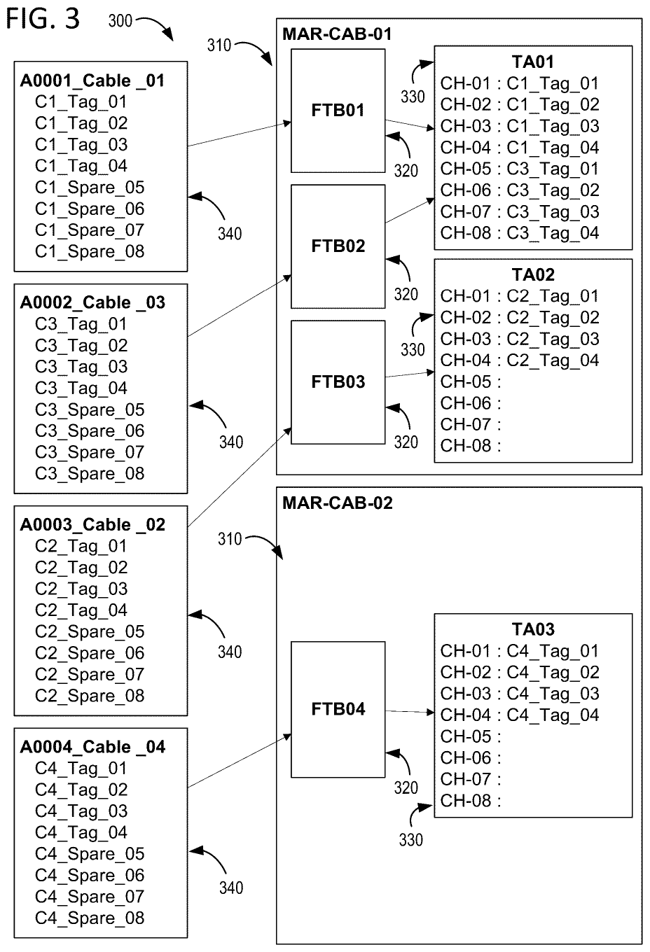

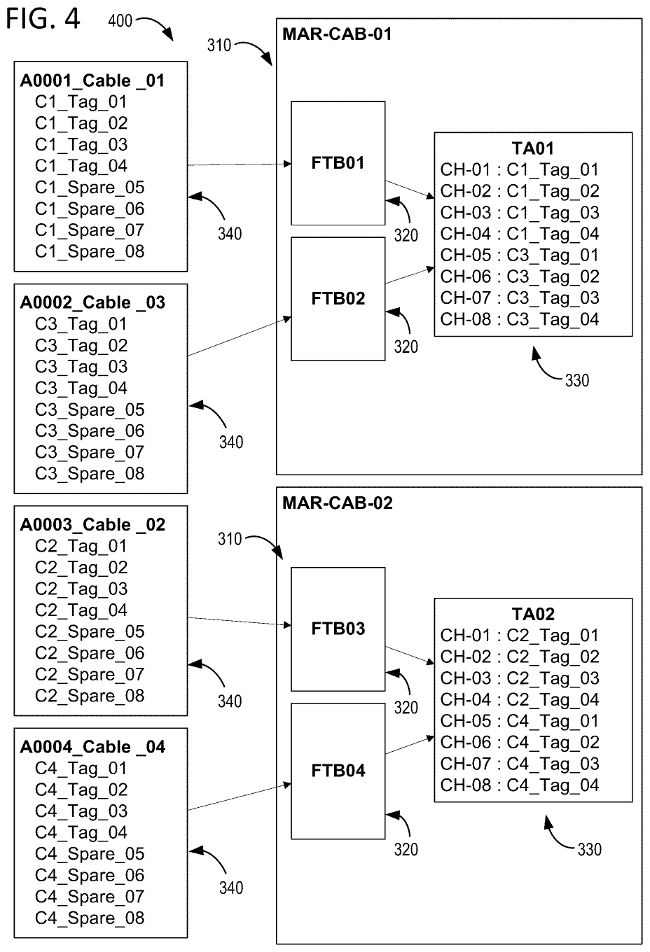

To illustrate the capabilities and advantages of the system 200, compare FIG. 3, which shows an ICS 300 with two marshalling cabinets 310 configured manually, and FIG. 4, which shows an ICS 400 with the same two marshalling cabinets 310 configured using the system 200. In this example, the input data 202 specifies two marshalling cabinets 310, each capable of housing up to three field terminal blocks 320 and two terminal assemblies 330. The input data 202 also specifies four cables 340 carrying signals to the cabinets 310 from another instrument or device (e.g., field device 110, PLC 111, sensor 112, supervisory computer 120, network device 132). Table 1 provides example input data 202 for these four cables 340. Each cable 340 has a size of “8” and can thus carry up to eight signals (e.g., via eight wires). Each signal or wire within a cable 340 may be assigned a specific function, destination, or other defining parameter, such as a signal type (e.g., analog input, digital output) and/or a voting designation (e.g., “A”, “B”). To facilitate structured wiring management, each signal or wire may be tagged with a unique identifier (e.g., C1_Tag_01, C1_Tag_02). The input data 202 in Table 1 specifies only four tags for each cable 340 (e.g., C1_Tag_01, C1_Tag_02, C1_Tag_03, C1_Tag_04), corresponding to the active signals or wires.

TABLE 1

| | | Signal | Voting | Cable |
|---|---|---|---|---|
| Cable Name | Tag Name | Type | Designation | Size |
| A0001_Cable_01 | C1_Tag_01 | AI | A | 8 |
| | C1_Tag_02 | AI | A | |
| | C1_Tag_03 | AI | A | |
| | C1_Tag_04 | AI | A | |
| A0001_Cable_02 | C2_Tag_01 | AI | B | 8 |
| | C2_Tag_02 | AI | B | |
| | C2_Tag_03 | AI | B | |
| | C2_Tag_04 | AI | B | |
| A0001_Cable_03 | C3_Tag_01 | AI | A | 8 |
| | C3_Tag_02 | AI | A | |
| | C3_Tag_03 | AI | A | |
| | C3_Tag_04 | AI | A | |
| A0001_Cable_04 | C4_Tag_01 | AI | B | 8 |
| | C4_Tag_02 | AI | B | |
| | C4_Tag_03 | AI | B | |
| | C4_Tag_04 | AI | B | |

FIG. 3 shows the ICS 300 in which the marshalling cabinets 310 are manually configured. The ICS 300 includes a first cabinet 310 (MAR-CAB-01) housing three field terminal blocks 320 (FTB01, FTB02, and FTB03) and two terminal assemblies (TA01 and TA02), and a second cabinet 310 (MAR-CAB-02) housing one field terminal block 320 (FTB04) and one terminal assembly (TA03). Three cables 340 (A0001_Cable_01, A0001_Cable_03, and A0001_Cable_02) are routed to the first cabinet 310 (MAR-CAB-01) and connected to three field terminal blocks 320 (FTB01, FTB02, and FTB03, respectively). Additionally, one cable 340 (A0001_Cable_04) is routed to the second cabinet 310 (MAR-CAB-02) and connected to the one field terminal block 320 (FTB04). As shown in FIG. 3, each cable 340 has four active signals or wires (e.g., C1_Tag_01, C1_Tag_02, C1_Tag_03, C1_Tag_04) and four inactive or unused signals or wires (e.g., C1_Spare_05, C1_Spare_06, C1_Spare_07, C1_Spare_08). In the first cabinet 310 (MAR-CAB-01), the signals from two cables 340 (A0001_Cable_01 and A0001_Cable_03) are routed to a first terminal assembly 330 (TA01), which is configured for analog input with “A” voting, and the signals from one cable 340 (A0001_Cable_02) are routed to a second terminal assembly 330 (TA02), which is configured for analog input with “B” voting. In the second cabinet 310 (MAR-CAB-02), the signals from one cable 340 (A0001_Cable_04) are routed to a third terminal assembly 330 (TA03), which is configured for analog input with “B” voting. As shown in FIG. 3, all eight channels are used or occupied in the first terminal assembly 330 (TA01), while only four channels are used in both the second terminal assembly 330 (TA02) and third terminal assembly 330 (TA03), leaving eight channels unoccupied, reflecting inefficient utilization of terminal space.

In contrast, FIG. 4 shows the ICS 400 in which the marshalling cabinets 310 are configured using the system 200, resulting in a more efficient configuration. The first cabinet 310 (MAR-CAB-01) now houses two field terminal blocks 320 (FTB01 and FTB02) and one terminal assembly (TA01), and the second cabinet 310 (MAR-CAB-02) now houses two field terminal blocks 320 (FTB 03 and FTB04) and one terminal assembly (TA02). Two cables 340 (A0001_Cable_01 and A0001_Cable_03) are routed to the first cabinet 310 (MAR-CAB-01) and connected to the two field terminal blocks 320 (FTB01 and FTB02, respectively). Additionally, two cables 340 (A0001_Cable_02 and A0001_Cable_04) are routed to the second cabinet 310 (MAR-CAB-02) and connected to the two field terminal blocks 320 (FTB03 and FTB04, respectively). As shown in FIG. 4, each cable 340 still has four active signals or wires (e.g., C1_Tag_01, C1_Tag_02, C1_Tag_03, C1_Tag_04) and four inactive or unused signals or wires (e.g., C1_Spare_05, C1_Spare_06, C1_Spare_07, C1_Spare_08). However, in the first cabinet 310 (MAR-CAB-01), the signals from two cables 340 (A0001_Cable_01 and A0001_Cable_03) are routed to a first terminal assembly 330 (TA01), which is configured for analog input with “A” voting (i.e., TA01). Moreover, in the second cabinet 310 (MAR-CAB-02), the signals from two cables 340 (A0001_Cable_02 and A0001_Cable_04) are routed to a second terminal assembly 330 (TA02), which is configured for analog input with both “A” and “B” voting. By redistributing the cables 340 and consolidating signal or wire assignments, the ICS 400 reduces the number of terminal assemblies, facilitating more efficient use of available space and enabling more structured wiring. In this manner, the system 200 provides a clean, logical, and protected layout, ensuring proper wire routing that enhances physical space management.

While the ICS 300 and ICS 400 both include two marshalling cabinets 310 with a particular configuration and include certain components and wiring with particular configurations, one skilled in the art would recognize and appreciate that the system 200 may be used to optimize any industrial control system, regardless of the number or configuration of industrial hardware enclosures, components, and/or wiring.

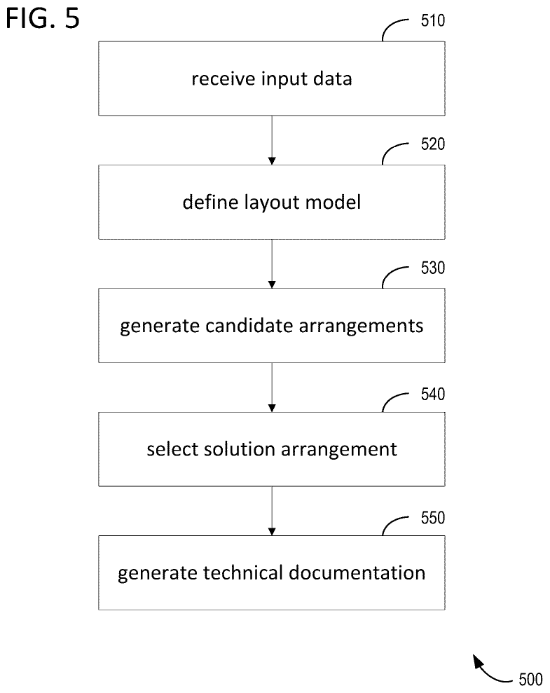

FIG. 5 shows an example method 500 for configuring at least one industrial hardware enclosure (e.g., cabinet 310). Input data 202 associated with the enclosure is received at operation 510. In some examples, the input data 202 may be processed or analyzed using a model generator 210 that identifies or determines variables 214, constraints 216, and objectives 218 based on the input data 202.

The variables 214, constraints 216, and objectives 218 are used to define a layout model 212 at operation 520. In some examples, the layout model 212 may be defined using a model generator 210 that incorporates or balances the variables 214, constraints 216, and objectives 218. In some examples, the model generator 210 may use machine learning techniques to refine or improve the layout model 212, systematically testing different combinations of variables 214, constraints 216, and/or objectives 218. Each combination may be assessed or evaluated to determine which configuration best represents the task of configuring the enclosure based on the input data 202.

The layout model 212 is used to generate a plurality of candidate arrangements 222 at operation 530. In some examples, the candidate arrangements 222 may be generated using a layout generator 220 that systematically adjusts values for the variables 214 within the layout model 212 and evaluates the candidate arrangements 222 based on their compliance with constraints 216 and alignment with objectives 218. By adjusting the values, the layout generator 220 may assess or evaluate how each variable 214 influences the outcome.

A solution arrangement 224 is selected at operation 540. In some examples, the solution arrangement 224 may be selected using a layout generator 220 that determines or identifies, from the candidate arrangements 222, one that best achieves the objectives 218 and satisfies all the constraints 216. In some examples, the layout generator 220 may use machine learning techniques to refine or improve the candidate arrangements 222, systematically adjusting values for the variables 214 to identify or determine the solution arrangement 224.

The solution arrangement 224 is used to generate technical documentation 232, such as a layout diagram illustrating component and wiring placements within the enclosure, at operation 560. In some examples, the technical documentation 232 may be generated using a document generator 230 that analyzes the solution arrangement 224 and generates the technical documentation 232 such that the technical documentation 232 are configured to facilitate the manufacturing, installation, and/or maintenance of the enclosure. For example, the technical documentation 232 may be generated to be in a machine-readable format that enables the components and wiring to be automatically assembled according to the solution arrangement 224 based on the technical documentation 232.

In an embodiment, the method 500 may be reapplied on completed and implemented designs for the purpose of applying further modifications of inputs.

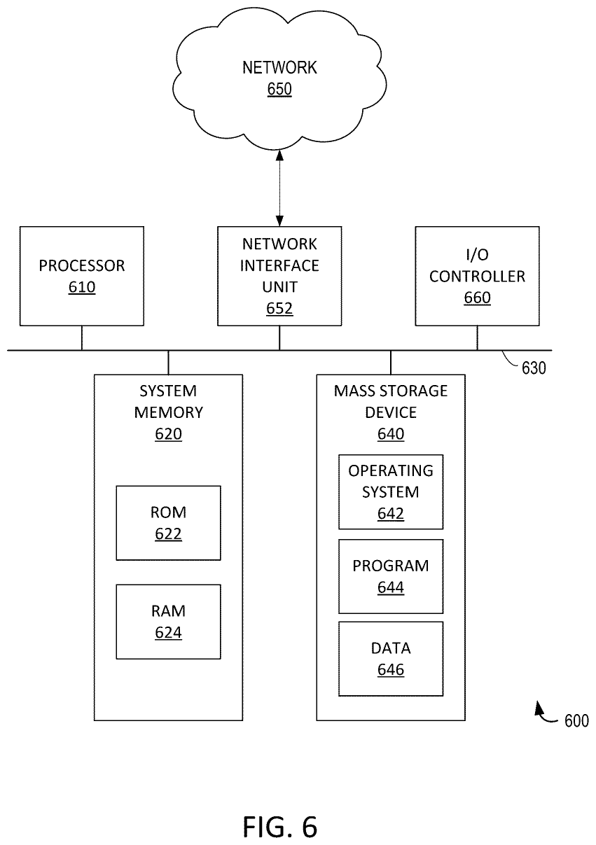

FIG. 6 shows an example computing system 600 (e.g., field device 110, PLC 111, supervisory computer 120, network device 132, system 200, model generator 210, layout generator 220, document generator 230) configured to perform one or more computing operations described herein. In some examples, the computing system 600 includes a processor 610, a system memory 620, and a bus 630 coupling various system components including the system memory 620 to the processor 610.

The processor 610 is configured to perform general computing functions and process data and instructions to perform one or more operations and/or provide other functionality described herein. For example, the processor 610 may access the system memory 620 to read data and instructions from and/or write data and instructions to the system memory 620 for use in executing one or more computer-executable instructions. In this manner, the processor 610 may be programmed to execute any aspect of the software components described herein, including software components for executing, implementing, and/or employing the model generator 210 (shown in FIG. 2), layout generator 220 (shown in FIG. 2), document generator 230 (shown in FIG. 2), and/or method 500 (shown in FIG. 5). In some examples, the processor 610 may be or include any quantity of processing units including a central processing unit, a graphics processing unit, a field-programmable gate array (FPGA), a digital signal processor (DSP), or other hardware logic components including, without limitation, an Application-Specific Integrated Circuit (ASIC), Application-Specific Standard Product (ASSP), System-on-a-Chip System (SOC), Complex Programmable Logic Device (CPLD), etc.

The system memory 620 includes any combination of computer-readable media that may be accessed by the processor 610. In some examples, the system memory 620 includes a read-only memory (ROM) 622 which stores instructions for executing basic functions and a random access memory (RAM) 624 which temporarily stores data and instructions for actively used programs. For example, the RAM 624 may be used to host or store wiring data, component data, device data, system data, and the like, as well as one or more software components for executing, implementing, and/or employing the model generator 210 (shown in FIG. 2), layout generator 220 (shown in FIG. 2), document generator 230 (shown in FIG. 2), and/or method 500 (shown in FIG. 5).

Computer-readable media includes both communication media and computer storage media. Communication media typically embody computer-readable instructions, data structures, program modules, or other data in a modulated data signal, such as a carrier wave or other transport mechanism. The term “modulated data signal” means a signal that has one or more of its characteristics set or changed in a manner as to encode information in the signal. By way of example, and not limitation, communication media includes wired media, such as a wired network or direct-wired connection, and wireless media, such as acoustic, radio frequency, and infrared media.

In contrast, computer storage media include tangible forms of media that can store information such as computer-readable instructions, data structures, program modules, or other data. By way of example, and not limitation, computer storage media includes ROM 622, RAM 624, hard disk drives (HDDs), solid-state drives (SSDs), external hard drives, flash drives, optical storage media (e.g., compact discs (CDs), digital versatile discs (DVDs), and magnetic storage media (e.g., tape drives). For purposes of the present disclosure, computer storage media is mutually exclusive to communication media and excludes waves, signals, and other transitory or intangible forms of media.

It should be appreciated that the software components described herein, when loaded into the processor 610 and executed, may transform the processor 610 and the overall computing system 600 from a general-purpose computing system into a special-purpose computing system customized to facilitate the functionality described herein. More specifically, the computer-executable instructions contained within the software components described herein transform the processor 610 to operate or function as a finite-state machine by specifying how the processor 610 transitions between states, thereby transforming the transistors or other discrete circuit elements constituting the processor 610.

Encoding the software components described herein may also transform the physical structure of the computer-readable media described herein. The specific transformation of physical structure may depend on various factors, in different implementations of the present disclosure. Examples of such factors may include, but are not limited to, the technology used to implement the computer-readable media, whether the computer-readable media is characterized as primary or secondary storage, and the like. For example, if the computer-readable media is implemented as semiconductor-based memory, the software disclosed herein may be encoded on the computer-readable media by transforming the physical state of the transistors, capacitors, or other discrete circuit elements constituting the semiconductor-based memory. The software also may transform the physical state of such components in order to store data thereupon.

As another example, the computer-readable media disclosed herein may be implemented using magnetic or optical technology. In such implementations, the software presented herein may transform the physical state of magnetic or optical media, when the software is encoded therein. These transformations may include altering the magnetic characteristics of particular locations within given magnetic media. These transformations also may include altering the physical features or characteristics of particular locations within given optical media, to change the optical characteristics of those locations. Other transformations of physical media are possible without departing from the scope and spirit of the present description, with the foregoing examples provided only to facilitate this discussion.

In some examples, the computing system 600 includes a mass storage device 640 coupled to the processor 610 for hosting or storing data and instructions, such as an operating system 642, one or more programs 644, and/or data 646. One of ordinary skill in the art would understand that copies of at least some data and/or instructions hosted or stored in the mass storage device 640 may be at least temporarily stored in the system memory 620 to enable the computing system 600 to function as described herein.

As shown in FIG. 6, the computing system 600 may connect to a network 650 (e.g., network 130) through a network interface unit 652 connected to the bus 630. In this manner, the computing system 600 may operate in a networked environment in which the computing system 600 may use one or more remote devices (not shown) to host or store at least some data and/or to execute at least some instructions. Computer communication between computing systems can be a network transfer, a file transfer, an applet transfer, an email, a hypertext transfer protocol (HTTP) transfer, and so on.

In some examples, the computing system 600 may include one or more input/output (I/O) controllers 660 that facilitate communication and data transfer between the processor 610 and one or more I/O devices (not shown) configured to provide input and/or output capabilities. For example, a user may enter commands and information into the computing system 600 using one or more input devices, such as a keyboard, pointing device (e.g., mouse, trackball, touch pad, stylus), microphone, camera, scanner, accelerometer, and the like. Additionally or alternatively, the computing system 600 may present various forms of information, such as text, images, audio, video, alerts, and the like, using one or more output devices, such as a monitor, projector, printer, speaker, actuator, and the like. In some examples, the output device may be integrated with the input device (e.g., in a touchscreen panel or in a controller including a vibrating component).

While some examples are illustrated and described herein with reference to the computing system 600 being, including, or being included in the system 200 (shown in FIG. 2), aspects of the present disclosure are operable with any computing system that can execute computer-executable instructions to implement the operations and functionality associated with the computing system 600. It is also contemplated that the computing system 600 may not include all of the components shown in FIG. 6, may include other components that are not explicitly shown in FIG. 6, or may utilize an architecture completely different than that shown in FIG. 6. The computing system 600 should not be interpreted as having any dependency or requirement relating to any one or combination of components shown in FIG. 6. The computing system 600 is only one example of a computing and networking environment for performing one or more computing operations and is not intended to suggest any limitation as to the scope of use or functionality of the present disclosure.

Example methods and systems are described herein for designing and/or configuring industrial hardware enclosures effectively, efficiently, and consistently. Examples described herein translate a real-world engineering challenge into a structured set of mathematical relationships by modeling the design problem in terms of variables, constraints, and objectives and iterating through the variables to achieve the objectives and satisfy the constraints. A solution arrangement may then be used to load all marshalling and system components required (e.g., field terminal blocks, Ethernet terminal blocks, relays, point-to-point connections, input/output modules, etc.) and generate a hardware report.

Through iterative refinement, examples described herein define a layout model configured to improve component positioning, reduce wiring complexity, and enhance overall efficiency while maintaining compliance with industry standards and operational needs. By leveraging machine learning algorithms, the layout model systematically assesses potential configurations, ensuring that the solution arrangement aligns with both technical constraints and performance goals. This structured approach enables the design and configuration industrial hardware enclosures that balance functional, spatial, and safety considerations, ultimately improving the performance and reliability of the industrial hardware enclosure. Accordingly, examples described herein provide a scalable and systematic approach to the industrial hardware enclosure configuration, improving efficiency, consistency, and overall cost-effectiveness. In view of the above, it will be seen that several advantages of the disclosed systems and methods are achieved and other advantageous results attained.

Although described in connection with an example computing system environment, examples of the present disclosure are capable of implementation with numerous other general purpose or special purpose computing system environments, configurations, or devices. Examples of well-known computing systems, environments, and/or configurations that may be suitable for use with aspects of the disclosure include, but are not limited to, server computers, desktop computers, laptop computers, tablets, mobile devices, communication devices in wearable or accessory form factors, microprocessor-based systems, multiprocessor systems, programmable consumer electronics, kiosks, tabletop devices, industrial control devices, minicomputers, mainframe computers, network computers, distributed computing environments that include any of the above systems or devices, and the like.

Examples of the present disclosure may be described in the general context of computer-executable instructions, such as program modules, executed by one or more computers or other devices in software, firmware, hardware, or a combination thereof. The computer-executable instructions may be organized into one or more computer-executable modules or components. Generally, program modules include, but are not limited to, routines, objects, components, and data structures that perform particular tasks or implement particular abstract data types. Aspects of the disclosure may be implemented with any number and organization of such modules or components. For example, aspects of the present disclosure are not limited to the specific computer-executable instructions or the specific components or modules illustrated in the figures and described herein. Other examples of the present disclosure may include different computer-executable instructions or components having more or less functionality than illustrated and described herein.

In some examples, the operations illustrated in the drawings may be implemented as software instructions encoded on a computer readable medium, in hardware programmed or designed to perform the operations, or both. For example, aspects of the present disclosure may be implemented as a system on a chip or other circuitry including a plurality of interconnected, electrically conductive elements.

It is possible for one or more elements of an implementation of an apparatus as described herein to be used to perform tasks or execute other sets of instructions that are not directly related to an operation of the apparatus, such as a task relating to another operation of a device or system in which the apparatus is embedded. It is also possible for one or more elements of an implementation of such an apparatus to have structure in common (e.g., a processor used to execute portions of code corresponding to different elements at different times, a set of instructions executed to perform tasks corresponding to different elements at different times, or an arrangement of electronic and/or optical devices performing operations for different elements at different times).

The order of execution or performance of the operations in examples of the present disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the present disclosure.

The examples illustrated and described herein as well as examples not specifically described herein but within the scope of aspects of the present disclosure constitute example means for configuring an industrial hardware enclosure. For example, the elements illustrated in FIGS. 2 and 6 when programmed, encoded, or configured to perform the operations illustrated in FIG. 5, constitute at least an example means for receiving input data including information about one or more constraints, one or more objectives, and one or more variables associated with the at least one industrial hardware enclosure (e.g., system 200, model generator 210); an example means for defining a layout model that represents a task of configuring the at least one industrial hardware enclosure based on the one or more constraints, the one or more objectives, and the one or more variables (e.g., system 200, layout generator 220); an example means for generating a plurality of candidate arrangements by systematically adjusting values for the one or more variables within the layout model (e.g., system 200, layout generator 220); an example means for selecting, from the plurality of candidate arrangements, a solution arrangement that satisfies the one or more constraints and is aligned with at least one of the one or more objectives (e.g., system 200, layout generator 220); and an example means for generating a drawing packet based on the solution arrangement (e.g., system 200, document generator 230).

When introducing elements of aspects of the disclosure or the examples thereof, the articles “a,” “an,” “the,” and “said” are intended to mean that there are one or more of the elements. Furthermore, references to an “embodiment” or “example” of the present disclosure are not intended to be interpreted as excluding the existence of additional embodiments or examples that also incorporate the recited features. The terms “comprising,” “including,” and “having” are intended to be inclusive and mean that there may be additional elements other than the listed elements. The phrase “one or more of the following: A, B, and C” means “at least one of A and/or at least one of B and/or at least one of C.”

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

In the present description, reference numbers have sometimes been used in connection with various terms. Where a term is used in connection with a reference number, this may be meant to refer to a specific element that is shown in one or more of the figures. Where a term is used without a reference number, this may be meant to refer generally to the term without limitation to any particular figure.

Having described aspects of the disclosure in detail, it will be apparent that modifications and variations are possible without departing from the scope of aspects of the disclosure as defined in the appended claims. As various changes could be made in the above constructions, products, and methods without departing from the scope of aspects of the disclosure, it is intended that all matter contained in the above description and shown in the accompanying drawings shall be interpreted as illustrative and not in a limiting sense.

While aspects of the present disclosure have been described in terms of various examples with their associated operations, a person skilled in the art would appreciate that a combination of operations from any number of different examples is also within the scope of the aspects of the present disclosure.

What is claimed is:

1. A method for configuring at least one industrial hardware enclosure, the method comprising:
receiving input data associated with the at least one industrial hardware enclosure, wherein the input data includes information related to one or more variables, one or more constraints, and one or more objectives;
defining a layout model using the one or more variables, the one or more constraints, and the one or more objectives, wherein the layout model represents a task of configuring the at least one industrial hardware enclosure based on the input data;
generating a plurality of candidate arrangements by systematically adjusting values for the one or more variables within the layout model;
selecting, from the plurality of candidate arrangements, a solution arrangement that satisfies the one or more constraints and is aligned with at least one of the one or more objectives; and
generating technical documentation based on the solution arrangement, wherein the technical documentation include a layout diagram illustrating placement of one or more of components and wiring within the at least one industrial hardware enclosure.

2. The method of claim 1, further comprising analyzing the input data to determine the one or more variables, the one or more constraints, and the one or more objectives.

3. The method of claim 1, further comprising:
analyzing the input data to extract relevant information; and
classifying the relevant information as one of a variable, a constraint, or an objective.

4. The method of claim 1, further comprising analyzing the input data to determine at least one parameter directly related to the one or more components and wiring, including at least one of a physical specification, a power specification, a thermal specification, or a connectivity and compatibility specification.

5. The method of claim 1, further comprising analyzing the input data to determine at least one parameter related to an environmental condition.

6. The method of claim 1, further comprising analyzing the input data to determine at least one parameter related to at least one of a safety code, a certification, an industry standard, a hazardous area classification, or a fire resistance rating.

7. The method of claim 1, further comprising analyzing the input data to determine at least one user-related parameter.

8. The method of claim 1, further comprising analyzing the input data to determine at least one of a space constraint, an adjacency constraint, or a wiring segregation constraint.

9. The method of claim 1, wherein the one or more objectives include reducing a component count.

10. The method of claim 1, wherein defining the layout model comprises systematically testing a plurality of combinations of the one or more variables, the one or more constraints, and the one or more objectives.

11. The method of claim 1, further comprising iteratively evaluating the plurality of candidate arrangements for one or more physical considerations and one or more electrical considerations.

12. The method of claim 1, further comprising:
converting the technical documentation into a machine-readable format; and
controlling automated equipment, using the technical documentation in the machine-readable format, to perform at least one action automatically, the at least one action comprising at least one of positioning the components or routing the wiring within the at least one industrial hardware enclosure.

13. A computing system for configuring at least one industrial hardware enclosure, the computing system comprising:
a model generator configured to receive input data associated with the at least one industrial hardware enclosure, wherein the input data includes information related to one or more variables, one or more constraints, and one or more objectives, and define a layout model using the one or more variables, the one or more constraints, and the one or more objectives, wherein the layout model represents a task of configuring the at least one industrial hardware enclosure based on the input data;
a layout generator configured to use the layout model to generate a plurality of candidate arrangements by systematically adjusting values for the one or more variables within the layout model, and determine a solution arrangement that satisfies the one or more constraints and is aligned with at least one of the one or more objectives; and
a document generator configured to generate technical documentation based on the solution arrangement, wherein the technical documentation include a layout diagram illustrating placement of one or more of components and wiring within the at least one industrial hardware enclosure.

14. The computing system of claim 13, wherein the model generator is further configured to analyze the input data to extract relevant information and classify the relevant information as one of a variable, a constraint, or an objective.

15. The computing system of claim 13, wherein the model generator is further configured to systematically test a plurality of combinations of the one or more variables, the one or more constraints, and the one or more objectives.

16. The computing system of claim 13, wherein the document generator is further configured to convert the technical documentation into a machine-readable format and to control automated equipment to perform at least one action automatically, the at least one action comprising at least one of positioning the components or routing the wiring within the at least one industrial hardware enclosure, based on the technical documentation in the machine-readable format.

17. A system comprising:
an industrial hardware enclosure;
a plurality of components;
wiring; and
a computing device configured to:
receive input data associated with the industrial hardware enclosure, wherein the input data includes information related to one or more variables, one or more constraints, and one or more objectives,
define a layout model using the one or more variables, the one or more constraints, and the one or more objectives, wherein the layout model represents a task of configuring the industrial hardware enclosure based on the input data,
use the layout model to generate a plurality of candidate arrangements by systematically adjusting values for the one or more variables within the layout model,
determine a solution arrangement that satisfies the one or more constraints and is aligned with at least one of the one or more objectives, and
generate technical documentation based on the solution arrangement, wherein the technical documentation include a layout diagram illustrating placement of one or more of the plurality of components and the wiring within the industrial hardware enclosure.

18. The system of claim 17, wherein the computing device is further configured to analyze the input data to extract relevant information, and classify the relevant information as one of a variable, a constraint, or an objective.

19. The system of claim 17, wherein the computing device is further configured to systematically test a plurality of combinations of the one or more variables, the one or more constraints, and the one or more objectives.

20. The system of claim 17, wherein the computing device is further configured to convert the technical documentation into a machine-readable format and to control automated equipment to perform at least one action automatically, the at least one action comprising at least one of positioning the plurality of components or routing the wiring within the industrial hardware enclosure, based on the technical documentation in the machine-readable format.
